(19) United States
(12) Patent Application Publication
(10) Pub. No.: US 2017/0243845 A1
(43) Pub. Date: Aug. 24, 2017

(54) FAN-OUT WAFER-LEVEL PACKAGES WITH IMPROVED TOPOLOGY

(71) Applicant: QUALCOMM Incorporated, San Diego, CA (US)

(72) Inventors: Jae Sik Lee, San Diego, CA (US); Hong Bok We, San Diego, CA (US); Dong Wook Kim, San Diego, CA (US)

(21) Appl. No.: 15/048,906

(22) Filed: Feb. 19, 2016

(51) Int. Cl. H01L 23/00; H01L 23/31; H01L 21/78; H01L 21/56; H01L 21/3105

(52) U.S. Cl. CPC H01L 24/14; H01L 21/565; H01L 24/11; H01L 21/31051; H01L 21/31058; H01L 21/568; H01L 21/561; H01L 21/78; H01L 23/3135; H01L 2224/11462; H01L 2224/12105; H01L 2224/13147; H01L 2224/0231; H01L 2224/11334; H01L 2224/13024; H01L 2224/13015; H01L 2224/13016; H01L 2924/19105; H01L 2924/19041

(57) ABSTRACT

A fan-out wafer-level-process integrated circuit is provided in which a plurality of interconnects couple to pads on an encapsulated die. The interconnects have a pad-facing surface that couples to a corresponding pad through a seed layer. The seed layer does not cover the sidewalls of the interconnects.

### TECHNICAL FIELD

This application relates to fan-out wafer-level packages, and more particularly to a fan-out wafer-level package with improved topology.

### BACKGROUND

The explosive growth of the smartphone market has increased demand for functional convergence and die integration in the packaging arts. To meet this demand, fan-out wafer-level packages (FOWLP) packages have been developed. In a planar (2D) FOWLP, one or more dies are embedded in a molded wafer so that an active surface of each die is coplanar with a mold compound surface. A redistribution layer (RDL) may thus “fan out” from the active surface of the die onto the mold compound surface. In a 3D FOWLP, additional dies are stacked onto the active surface of the co-planar dies and wire bonded to the RDL over the mold compound surface. As compared to conventional package-on-package (PoP) technologies, a FOWLP eliminates the organic substrate so as to have reduced height and increased form factor as well as reduced cost.

Although FOWLP is thus an attractive packaging technology, its manufacture suffers from a number of drawbacks. For example, a polymer dielectric layer is typically deposited over the active surface of the coplanar dies and mold compound surface prior to deposition of the RDL and its associated vias. The polymer dielectric layer is then patterned so that the RDL vias may subsequently be deposited. To increase density, the via diameter and pitch must be relatively small, which requires the polymer dielectric layer to be relatively thin. Although the mold compound surface is coplanar with the active surface of the embedded dies, it is does not have the same height such that the relatively thin polymer dielectric layer covering the mold compound has an upper surface that is lower than the same polymer dielectric layer upper surface covering the dies. This step height difference leads to lithography issues when patterning the polymer dielectric layer prior to depositing the RDL vias.

Accordingly, there is a need in the art for fan-out wafer-level packages with improved topology.

### SUMMARY

A fan-out wafer-level-process (FOWLP) integrated circuit package is provided that includes a molded package in which at least one die is encapsulated in mold compound. The molded package has a mold compound surface in which an active surface of the at least one die is exposed. A plurality of interconnects extend through a polymer dielectric layer to couple to corresponding pads on the active surface of the at least one die. Each of the interconnects has a pad-facing surface that couples through a seed layer to the corresponding pad. In addition, the interconnects each have a longitudinally-extending metal body that ends at the pad-facing surface. A circumferential surface surrounds the longitudinally-extending metal body for each interconnect. A dielectric layer covers the mold compound surface and surrounds each interconnect such that the dielectric layer directly contacts the circumferential surface of the interconnect's longitudinally-extending metal body.

The direct contact between the circumferential surface for each interconnect and the dielectric layer results from the interconnects being formed prior to the deposition of the dielectric layer. In contrast, it is conventional to first pattern the dielectric layer so that vias may be electroplated or deposited through the dielectric layer to pads on the active surface of the encapsulated die (or dies) in the molded package. To obtain reduced pitch, the formation of such conventional vias required the dielectric layer to be relatively thin. But such relative thinness is problematic in light of the inevitable step height difference between the mold compound surface and the exposed active surface of the encapsulated dies. The relatively thin conventional dielectric layer thus retained this step height difference, which complicated the subsequent formation of a redistribution layer (RDL) over the conventional dielectric layer. In sharp contrast, the interconnects disclosed herein may be formed in a relatively thick photo-imageable layer such as a photoresist layer that is then removed after formation of the interconnects. The resulting interconnects may thus be relatively tall as compared to conventional vias. The subsequent deposition of the dielectric layer may thus result in a relatively-thick dielectric layer that does not have a stepped surface resulting from the step height differences on the mold compound surface. In this fashion, the resulting dielectric layer has a relatively planar topology so that the RDL may be accurately deposited. In addition to improving the lithography for the RDL, the improved dielectric layer herein is more robust to warpage. These advantageous features may be better appreciated through the disclosure of the following example embodiments.

### BRIEF DESCRIPTION OF THE DRAWINGS

FIG. 1A is a cross-sectional view of an example fan-out wafer-level-process (FOWLP) integrated circuit package in accordance with an aspect of the disclosure.

FIG. 1B is a cross-sectional view of an interconnect for the FOWLP integrated circuit package of FIG. 1A.

FIG. 2A is a cross-sectional view of the carrier and circuit components during the manufacture of the FOWLP integrated circuit package of FIG. 1A.

FIG. 2B is a cross-sectional view of the molded package after encapsulation with mold compound during the manufacture of the FOWLP integrated circuit package of FIG. 1A.

FIG. 2C is a cross-sectional view of the molded package from FIG. 2B after the carrier and adhesive layer are removed.

FIG. 2D is a cross-sectional view of the molded package from FIG. 2C after deposition of the micro-bumps.

FIG. 2E is a cross-sectional view of the molded package from FIG. 2D after deposition of the polymer dielectric layer.

FIG. 3 is a flowchart for an example method of manufacture of the FOWLP integrated circuit package of Figure 1A.

FIG. 4 illustrates some example electronic systems incorporating an FOWLP integrated circuit package in accordance with an embodiment of the disclosure.

Embodiments of the disclosure and their advantages are best understood by referring to the detailed description that follows. It should be appreciated that like reference numerals are used to identify like elements illustrated in one or more of the figures.

### DETAILED DESCRIPTION

To provide improved topology, a fan-out wafer-level package (FOWLP) is provided in which a plurality of interconnects are deposited onto a molded package prior to the deposition of a dielectric layer such as a polymer dielectric layer. The molded package has a mold compound surface in which an active surface of one or more dies is exposed. The active surface includes a plurality of pads corresponding to the plurality of interconnects. After deposition of the plurality of interconnects, each pad couples to a corresponding interconnect. The polymer dielectric layer is then deposited over the mold compound surface so as to surround each interconnect. Since the polymer dielectric layer no longer needs to be patterned and etched for the formation of any vias to couple to the pads, the polymer dielectric layer may be relatively thick. In this fashion, an opposing surface of the polymer dielectric layer that faces away from the active surface of the mold-compound-embedded die(s) may be relatively planar despite step height differences between the active surface of encapsulated die(s) and the mold compound surface in the molded package. The metal layers for a redistribution layer (RDL) may then be deposited over the planar surface of the polymer dielectric layer without lithography issues caused by non-planarity. In addition, the relative thickness of the polymer dielectric layer enables its deposition in some embodiments in laminar or spin coating layers that inhibit warpage of the resulting FOWLP. These advantageous features may be better appreciated through the following example embodiments.

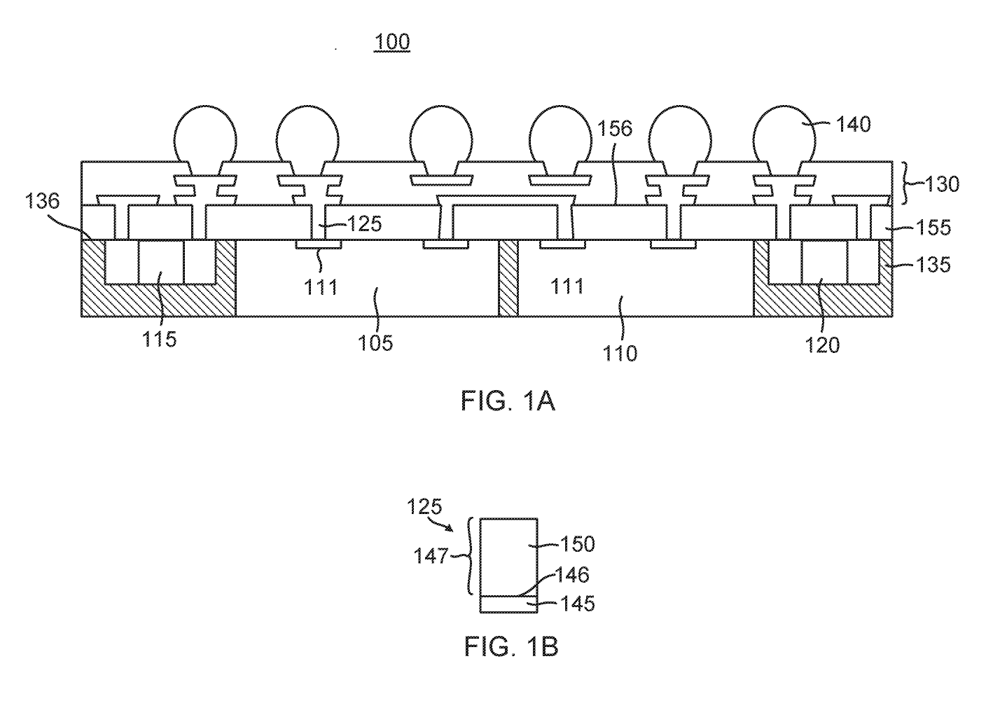

Turning now to the drawings, an example FOWLP 100 is shown in FIG. 1A. A die 105 and a die 110 are embedded in mold compound 135 such that each die's active surface with pads 111 is exposed within a mold compound surface 136 of mold compound 135. The active surface for each die 105 and 110 is thus aligned or coplanar with mold compound surface 136 such that mold compound surface 136 circumferentially surrounds each active surface. Although mold compound surface 136 and the active surfaces are coplanar, the encapsulation of dies 105 and 110 by mold compound 135 may result in a step height difference (not illustrated) between mold compound surface 136 and the active surface for each of dies 105 and 110. This step height difference, however, advantageously does not result in a step height difference in a planar surface 156 for a dielectric layer such as a polymer dielectric layer 155 as discussed further herein. Analogous to dies 105 and 110, a capacitor 115 and a capacitor 120 may be encapsulated by mold compound 135. Each capacitor 115 and 120 has a contact surface having a plurality of contacts or pads exposed in mold compound surface 136 such that mold compound surface 136 circumferentially surrounds each capacitor contact surface. Just like the active surfaces for dies 105 and 110, the contact surface for each capacitor 115 and 120 is coplanar and aligned with mold compound surface except for any relatively-small step height difference (e.g., several microns).

It will be appreciated that additional dies may be encapsulated in mold compound 135 in alternative embodiments. Moreover, just a single die may be encapsulated (or embedded) in mold compound 135 in alternative embodiments. In addition, the number and type of embedded passive components such as capacitors 115 and 120 may be changed in alternative embodiments. For example, inductors may also be encapsulated in mold compound 135 analogously as discussed with regard to capacitors 115 and 120

A first plurality of interconnects 125 such as copper pillars (or other suitable interconnects) are deposited onto pads 111 for the active surface of die 105 and die 110 prior to the deposition of polymer dielectric layer 155. Each pad 111 thus couples to at least one corresponding interconnect 125. A second plurality of interconnects 125 couples to the plurality of contacts for capacitors 115 and 120. Each contact thus couples to at least one corresponding interconnect 125. As will be explained further herein, interconnects 125 may be relatively tall such as 10-35 microns. The subsequent deposition of polymer dielectric layer 155 surrounds these relative tall interconnects 125 such that polymer dielectric layer 155 is also relatively thick. In this fashion, the relative thickness of polymer dielectric layer 155 enables its opposing surface 156 to be planar despite the step height differences between the underlying mold compound surface 136 and the active surfaces for dies 105 and 110 and despite the step height differences between the underlying mold compound surface 136 and the contact surfaces for capacitors 115 and 120. The relative thickness of polymer dielectric layer 155 effectively “smooths over” these step height differences so that its opposing surface 156 is relatively planar. In contrast, a conventional polymer dielectric layer needs to be relatively thin so that its vias may have reduced pitch. The conventional polymer dielectric layer thus has an opposing surface that mirrors these step height differences. Due to the resulting planarity for opposing surface 156 of polymer dielectric layer 155, the metal layer(s) for a redistribution layer (RDL) 130 may then be accurately deposited onto opposing surface 156. Solder balls 140 couple to RDL 130 so that FOWLP 100 may be mounted onto a circuit board or other structure.

An interconnect 125 is shown in a close-up view in FIG. 1B. Since interconnect 125 was deposited prior to the deposition of polymer dielectric layer 155, a seed layer 145 will not coat the sidewalls of interconnect but instead will only cover a pad-facing (or contact facing) surface 146 of interconnect 125. Seed layer 145 in turn contacts one of pads 111 or a contact for capacitors 115 and 120. A longitudinally-extended metal body 150 such as a copper fill or other suitable metal completes interconnect 125. A circumferential surface 147 for metal body 150 thus directly contacts polymer dielectric layer 155 (FIG. 1A) without any intervening seed layer.

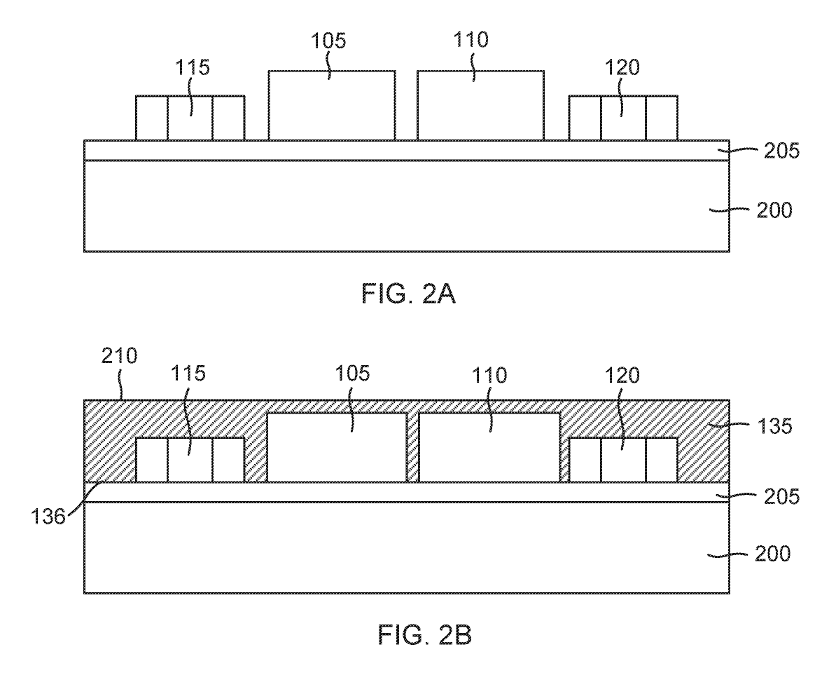

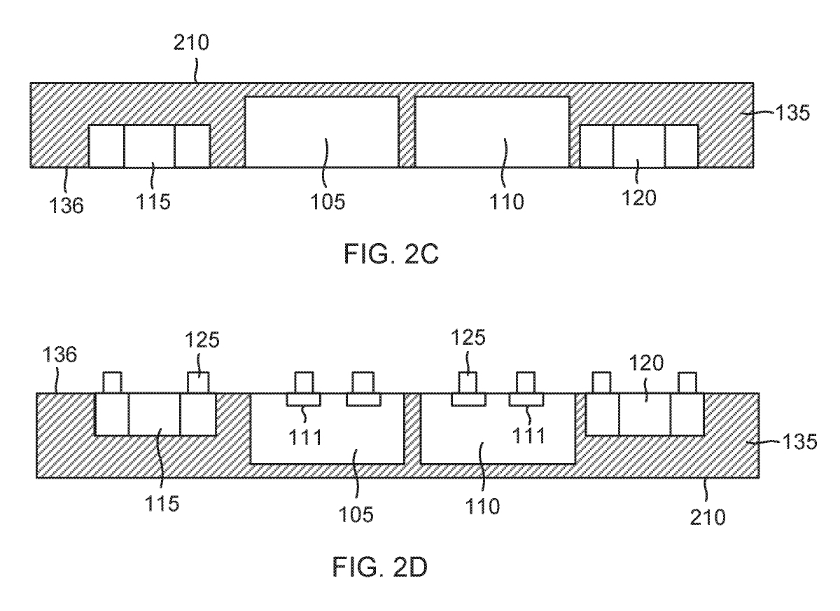

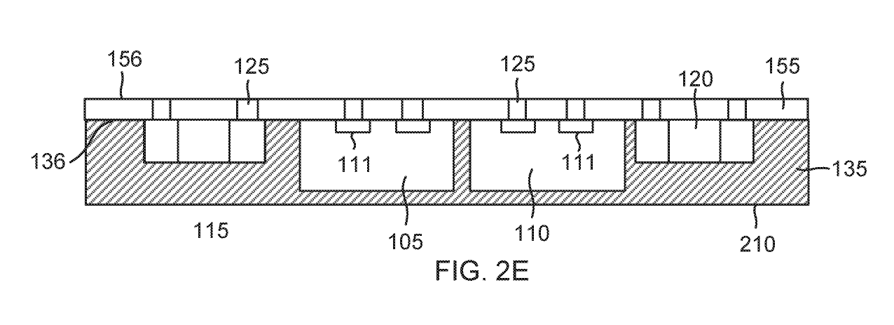

An example method of manufacture for FOWLP 100 will now be discussed. As shown in FIG. 2A, dies 105 and 110 may have their active surfaces coupled to a carrier 200 through a double-sided adhesive layer (double-sided tape) 205. The pad or contact surface for each of capacitors 115 and 120 is similarly attached to adhesive layer 205. It will be appreciated that the remainder of the wafer from which dies 105 and 110 are singulated as is conventional in a wafer-level process is not shown in FIG. 2A for illustration clarity.

Dies 105 and 110 and capacitors 115 and 120 may then be encapsulated with mold compound 135 to form a molded package 210 as shown in FIG. 2B. Note that mold compound 135 is encapsulating only the sides and back surfaces of dies 105 and 110 since the active surface of these dies is facing adhesive layer 205. Similarly, mold compound 135 encapsulates only the back surface and sides of capacitors 115 and 120 since the pad surface for each of these capacitors is adhered to adhesive layer 205. Carrier 200 and double-sided adhesive layer 205 may then be removed from molded package 210 shown in FIG. 2C.

The resulting molded package 210 may then be flipped as shown in FIG. 2D to expose the pads for dies 105 and 110 as well as for capacitors 115 and 120. Due to the previous adhesion to adhesive layer 205 discussed with regard to FIGS. 2A-2B, mold compound surface 136 and the active surface for each of dies 105 and 110 are coplanar except for any minor step height differences (for example, a few microns). Similarly, mold compound surface 136 and the contact surface for each of capacitors 115 and 120 are coplanar but for any minor step height differences. Seed layer 145 of FIG. 1B may then be deposited onto mold compound surface 136, the active surface of each die 105 and 110, and the contact surface for each of capacitors 115 and 120. Seed layer 145 may then be covered by a photo-imageable polymer layer (not illustrated) such as a photoresist layer that may be patterned using photolithography. The patterned photoresist layer may then be electrochemically plated (ECP) to form interconnects 125 such as micro-bumps or copper pillars onto pads 111 of dies 105 and 110 and also onto the contacts for capacitors 115 and 120. The photoresist layer is then removed followed by an etching of seed layer 145. Interconnects 125 thus have the profile discussed with regard to FIG. 1B in that seed layer 145 is absent from the sidewalls 147. Since photoresist layer 145 will be removed, it may be deposited relatively thickly such as a thickness of 10-35 microns. Interconnects 125 will then have a height matching this relative thickness.

As shown in FIG. 2E, polymer dielectric layer 155 may then be deposited over dies 105 and 110, capacitors 115 and 120, and mold compound surface 136. Polymer dielectric layer 135 may be relatively thick so that it may surround circumferential surface 147 along the entire longitudinal extent of metal body 150 (FIG. 1B) for each interconnect 125. For example, polymer dielectric layer 155 may be laminated or spun over dies 105 and 110, capacitors 115 and 120, and the exposed surface of mold compound 135. In general, polymer dielectric layer 155 will be deposited such that it actually covers interconnects 125. To expose interconnects 125, opposing surface 156 of polymer dielectric layer 155 may then be flattened such as through grinding, chemical mechanical polishing, or fly cutting. Alternatively, lithography and RDL may be used to interconnects 125. Referring again to FIG. 1A, a semi-additive process may then be used to complete RDL 130 followed by deposition of balls 140 to complete FOWLP 100.

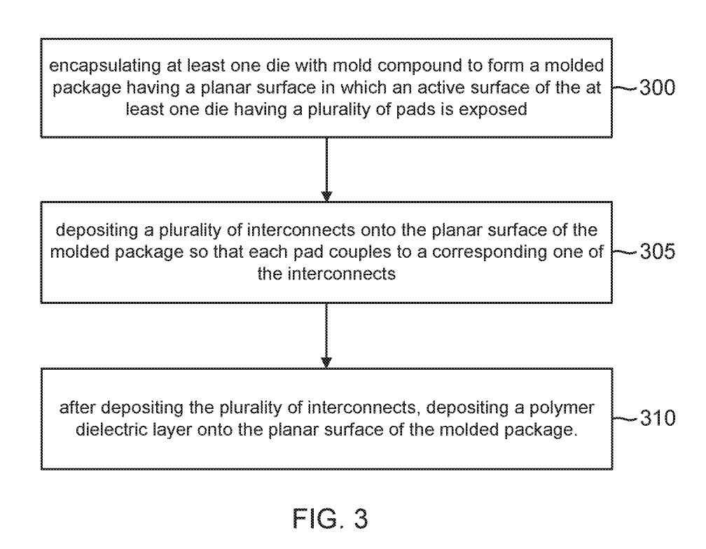

The method of manufacturing FOWLP 100 may be summarized with regard to the flowchart of FIG. 3. The method includes an act 300 of encapsulating at least one die with mold compound to form a molded package having a planar surface in which an active surface of the at least one die having a plurality of pads is exposed. The formation of molded package 210 discussed with regard to FIG. 2B and FIG. 2C is an example of act 300. The method further includes an act 305 of depositing a plurality of interconnects onto the planar surface of the molded package so that each pad couples to a corresponding one of the interconnects. The deposition of micro-bumps or interconnects 125 as discussed with regard to FIG. 2D is an example of act 305. Finally, the method includes an act 310 performed after the deposition of the plurality of interconnects and comprises depositing a polymer dielectric layer onto the planar surface of the molded package. The deposition of polymer dielectric layer 155 discussed with regard to FIGS. 1A and 2E is an example of act 310.

An example electronic system will now be discussed.

### Example Electronic Systems

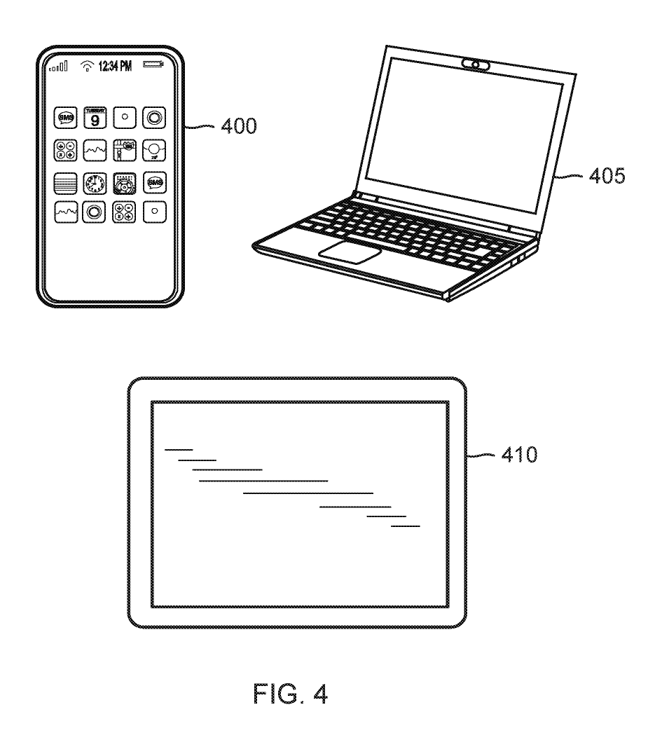

A FOWLP integrated circuit package as disclosed herein may be incorporated into a wide variety of electronic systems. For example, as shown in FIG. 4, a cell phone 400, a laptop 405, and a tablet PC 410 may all include an FOWLP integrated circuit package constructed in accordance with the disclosure. Other exemplary electronic systems such as a music player, a video player, a communication device, and a personal computer may also be configured with integrated circuit packages constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1-11. (canceled)

12. A fan-out wafer-level-process (FOWLP) integrated circuit package, comprising:
at least one die including an active surface having a plurality of pads;
a mold compound configured to encapsulate the at least one die such that an active surface of the at least one die is exposed and coplanar with a surface of the mold compound; and
a plurality of first interconnects corresponding to the plurality of pads, wherein each first interconnect includes a pad-facing surface coupled to the corresponding pad, and wherein each first interconnect further includes a seed layer only on its pad-facing surface.

13. The FOWLP integrated circuit package of claim 12, further comprising a polymer dielectric layer surrounding the plurality of first interconnects and covering the active surface of the at least one die and the surface of the mold compound.

14. The FOWLP integrated circuit package of claim 12, wherein the at least one die comprises a plurality of dies.

15. The FOWLP integrated circuit package of claim 13, further comprising a redistribution layer covering the polymer dielectric layer and coupled to the plurality of first interconnects.

16. The FOWLP integrated circuit package of claim 15, further comprising a plurality of solder balls coupled to the redistribution layer.

17. The FOWLP integrated circuit package of claim 12, further comprising:
at least one passive circuit including a contact surface having a plurality of contacts, wherein the at least one passive circuit is encapsulated in the mold compound such that the contact surface is exposed and coplanar with the mold compound surface;
a plurality of second interconnects corresponding to the plurality of contacts, wherein each second interconnect includes a contact-facing surface coupled to the corresponding contact, and wherein each second interconnect includes a seed layer only on its contact-facing surface.

18. The FOWLP integrated circuit package of claim 17, wherein the polymer dielectric layer is configured to surround the plurality of second interconnects.

19. The FOWLP integrated circuit package of claim 17, wherein the at least one passive circuit comprises at least one capacitor.

20. A fan-out wafer-level-process (FOWLP) integrated circuit, comprising:
a molded package having a mold compound surface in which an active surface of at least one die is exposed, the active surface including a plurality of pads;
a plurality of interconnects coupled to the plurality of pads, each interconnect having a longitudinally-extending metal body having a circumferential surface;
a dielectric layer on the mold compound surface, the dielectric layer being configured to directly contact and surround the circumferential surface of the metal body for each interconnect.

21. The FOWLP integrated circuit of claim 20, further comprising a redistribution layer (RDL) on the dielectric layer.

22. The FOWLP integrated circuit of claim 20, wherein the FOWLP integrated circuit is integrated into a mobile electronic system selected from the group consisting of a cellular phone, a laptop, and a tablet.
